(19) United States
(12) Patent Application Publication
(10) Pub. No.: US 2025/0199036 A1
(43) Pub. Date: Jun. 19, 2025

(54) CURRENT SENSOR AND BUS BAR

(71) Applicant: Alps Alpine Co., Ltd., Tokyo (JP)

(72) Inventors: Keisuke NAKAYAMA, Miyagi-ken (JP); Manabu TAMURA, Miyagi-ken (JP)

(21) Appl. No.: 18/930,036

(22) Filed: Oct. 29, 2024

(30) Foreign Application Priority Data
Dec. 19, 2023 (JP) 2023-214078

(51) Int. Cl. G01R 19/00; G01R 33/09

(52) U.S. Cl. CPC G01R 19/0092; G01R 31/68; G01R 33/091

(57) ABSTRACT

A current sensor has a bus bar and a magnetic sensor. The bus bar has a portion extending in the X direction. A convex portion is formed on a plate surface, which is on the Z2 side, along the X direction, so as to protrude from the plate surface, the plate surface facing the magnetic sensor parallel to an XY plane defined by the X direction and the Y direction orthogonal to the X direction.

### CLAIM OF PRIORITY

This application claims benefit of Japanese Patent Application No. 2023-214078 filed on Dec. 19, 2023, which is hereby incorporated by reference.

### BACKGROUND OF THE INVENTION

### 1. Field of the Invention

The present invention relates to a current sensor that measures a current under test that flows in a bus bar and to the bus bar used in the current sensor.

### 2. Description of the Related Art

In recent years, a current sensor that measures a current under test that flows in a device is used to control a power supply system in a vehicle or the like that has various devices. Nowadays, needs for downsizing, profile reduction, weight reduction, and other requirements are growing for the current sensor. One means for downsizing the current sensor is to slim the bus bar included in the current sensor. If the bus bar is slimmed, however, when, for example, the bus bar and an external terminal or the like are fastened together, the bus bar may be deformed because stress is applied to the bus bar in a direction in which the bus bar is twisted or bent. Alternatively, the amount of heat may be increased, which is generated when a current under test flows in the bus bar. If the bus bar is deformed or the amount of heat generation is increased, detection precision of the current sensor may be lowered.

Japanese Unexamined Patent Application Publication No. 2012-163454 discloses a current detection mechanism intended to properly detect a current flowing in the bus bar, with the suppression of the overheat of an element due to a large amount of heat generation in the bus bar. In the bus bar in the current detection mechanism, a concave portion recessed from the surface or a through-hole extending from the front surface to the rear surface is formed at a position facing at least a magnetism detection element.

Japanese Unexamined Patent Application Publication No. 2018-151406 discloses a current detection structure intended to enable a magnetism detection element with high sensitivity to be used even when a large current flows in the bus bar and thereby achieve highly precise measurement. In the current detection structure, the magnetism detection element is placed in space enclosed by a bus bar formed in a concave shape, the position of the magnetism detection element being at the center of the bus bar in the width direction. Therefore, the magnetism detection element can detect only a magnetic field generated due to a current flowing in an upper wall positioned at the bottom of the concave shape of the bus bar.

In Japanese Unexamined Patent Application Publication No. 2012-163454 and Japanese Unexamined Patent Application Publication No. 2018-151406, however, there is no description for the problem of reduction in the strength of the bus bar due to slimming and for a solution for the problem.

### SUMMARY OF THE INVENTION

The present invention provides a current sensor in which a bus bar is less likely to be deformed even when stress is applied to the bus bar in a direction in which the bus bar is twisted or bent and that is advantageous in downsizing, profile reduction, and weight reduction, with the suppression of reduction in the strength of the bus bar due to slimming, and also provides the bus bar used in the current sensor.

The present invention has a structure below as a means for solving the problems described above. A current sensor has a bus bar and a magnetic sensor. The bus bar has a portion extending in a first direction. A convex portion is formed on a plate surface along the first direction, the plate surface being defined by the first direction and a second direction orthogonal to the first direction.

Since the strength of the bus bar is improved by forming the convex portion along the first direction, the bus bar is less likely to be deformed even when stress is applied to the bus bar in a direction in which the bus bar is twisted or bent during the attachment of the bus bar to the outside. Thus, it is possible to provide a current sensor for which profile reduction, downsizing, and weight reduction are achieved by sliming the bus bar.

The bus bar may have a narrow-width portion formed at a position facing the magnetic sensor in a third direction orthogonal to the first direction and second direction, and may also have wide-width portions, each of which has a larger dimension in the second direction than the narrow-width portion, on both sides of the narrow-width portion in the first direction, the wide-width portions being continuous to the narrow-width portion. The convex portion may be formed on the narrow-width portion.

Since the narrow-width portion is formed in the bus bar, the influence of the skin effect at a high frequency can be suppressed at the narrow-width portion. Therefore, when the magnetic sensor is placed so as to face the narrow-width portion and an induced magnetic field is measured with the magnetic sensor, the induced magnetic field being generated from the narrow-width portion due to a flow of the current under test in the narrow-width portion, measurement precision of the current sensor is improved.

The convex portion may be formed so as to be continuous from one wide-width portion through the narrow-width portion to the other wide-width portion.

Due to the convex portion continuously formed across both wide-width portions through the narrow-width portion, a force can be dispersed to the whole of the bus bar with the suppression of an abrupt change in strength on the boundary between the narrow-width portion and the wide-width portion. Therefore, the strength of the slimmed bus bar is improved.

With the bus bar, the convex portion may be formed on a first plate surface and a concave portion may be formed in a second plate surface, which is on the opposite side to the first plate surface, along the first direction. The magnetic sensor may be placed so as to face the concave portion.

Since the concave portion is formed, components of the induced magnetic field generated from the bus bar, the components being parallel to a detection surface of the magnetic sensor, can be increased. Thus, when the magnetic sensor is placed so as to face the concave portion in the bus bar, measurement precision of the current sensor is improved.

With the bus bar, the convex portion and concave portion may be formed at the same position when viewed along the third direction.

The strength of the bus bar can be improved by the convex portion, and measurement precision of the current sensor can be improved by the concave portion. Since the bus bar, with the convex portion and concave portion formed at the same position when viewed along the third direction, can be easily formed by half punching processing or the like, the bus bar is advantageous from the viewpoint of the manufacturing efficiency.

The current sensor may have a case in which the magnetic sensor is stored. The bus bar may be insert-molded into the case.

When the bus bar insert-molded into the case, a positional relationship can be fixed and maintained between the bus bar and the magnetic sensor. Therefore, measurement precision of the current sensor becomes superior.

A current sensor has a magnetic sensor and a case. The case has an insertion hole into which a bus bar, on the plate surface of which a convex portion is formed along the extending direction of the bus bar, can be inserted.

The insertion hole may have a guide through which the convex portion is passed.

When the bus bar is inserted into the insertion hole formed in the case, a current sensor having a bus bar can be manufactured. When a guide is formed in the insertion hole, the bus bar can be easily inserted into the insertion hole, so the manufacturing efficiency of the current sensor is improved.

A bus bar having a portion extending in a first direction has: a plate surface defined by the first direction and a second direction orthogonal to the first direction; a narrow-width portion formed at a position facing a magnetic sensor in a third direction orthogonal to the first direction and second direction, and wide-width portions, each of which has a larger dimension in the second direction than the narrow-width portion, on both sides of the narrow-width portion in the first direction, the wide-width portions being continuous to the narrow-width portion. A convex portion is formed on the narrow-width portion along the first direction.

Since the strength of the narrow-width portion is improved by forming the convex portion on the narrow-width portion along the first direction, it is possible to provide a bus bar that is less likely to be deformed even when stress is applied to the bus bar in a direction in which the bus bar is twisted or bent and is advantageous in downsizing, profile reduction, and weight reduction.

According to the present invention, the strength of the bus bar is improved by a convex portion, so profile reduction, downsizing, and weight reduction can be achieved for the current sensor, with the suppression of reduction in the strength of the bus bar due to slimming.

### BRIEF DESCRIPTION OF THE DRAWINGS

FIG. 1 is a perspective view schematically illustrating the structure of the main elements of a current sensor in an embodiment of the present invention;

FIG. 2 is a sectional view schematically illustrating the structure of the current sensor in FIG. 1 as taken along line II-II;

FIG. 3 is a perspective view illustrating the structure of a bus bar in the current sensor in FIG. 1;

FIG. 4A is a perspective view illustrating simulation results for deviation caused when a force is applied in the Z1 direction to an end of the bus bar in FIG. 3 on the X1 side;

FIG. 4B is a perspective view illustrating simulation results for deviation caused when a force is applied in the Z1 direction to an end of the bus bar in FIG. 15 on the X1 side;

FIG. 5 is a perspective view illustrating the structure of a variation of the bus bar in the current sensor in FIG. 1;

FIG. 6 is a perspective view schematically illustrating the structure of the main elements in the variation of the current sensor in FIG. 1;

FIG. 7 is a sectional view schematically illustrating the structure of the current sensor in FIG. 6 as taken along line VII-VII;

FIG. 8A illustrates simulation results indicating the strength of an induced magnetic field around the periphery of the bus bar in the current sensor in the embodiment in FIG. 6;

FIG. 8B illustrates simulation results indicating the strength of an induced magnetic field around the periphery of the bus bar in a current sensor in related art in FIG. 14;

FIG. 9 illustrates simulation results indicating the directions and strength of an induced magnetic field around the periphery of the bus bar for the variation of the bus bar in the current sensor in FIG. 6;

FIG. 10 illustrates simulation results indicating the directions and strength of an induced magnetic field around the periphery of the bus bar in a reference example;

FIG. 11 is a perspective view schematically illustrating a structure in another variation of the current sensor in FIG. 1;

FIG. 12 is an exploded perspective view schematically illustrating the structure in the other variation of the current sensor in FIG. 1;

FIG. 13 is a perspective view illustrating a state in which the current sensor in FIG. 12 has been assembled;

FIG. 14 is a perspective view schematically illustrating the structure of the main elements of the current sensor in related art; and

FIG. 15 is a perspective view illustrating the structure of a bus bar in the current sensor in FIG. 14.

### DESCRIPTION OF THE PREFERRED EMBODIMENTS

An embodiment of the present invention will be described below with reference to the attached drawings. Identical members are assigned identical reference characters in the drawings and descriptions will be omitted. A reference coordinate system is appropriately indicated on each drawing to indicate positional relationship among individual members. In the reference coordinate system, the extending direction of a bus bar will be taken as the X direction; the direction of the width dimension of the bus bar, the direction being orthogonal to the X direction, will be taken as the Y direction; and the direction in which the bus bar and a magnetic sensor are placed so as to be spaced apart, the direction being orthogonal to the X direction and Y direction, will be taken as the Z direction. The Y direction matches the direction of the sensitive axis of the magnetic sensor. The X direction and Z direction are orthogonal to the sensitive axis.

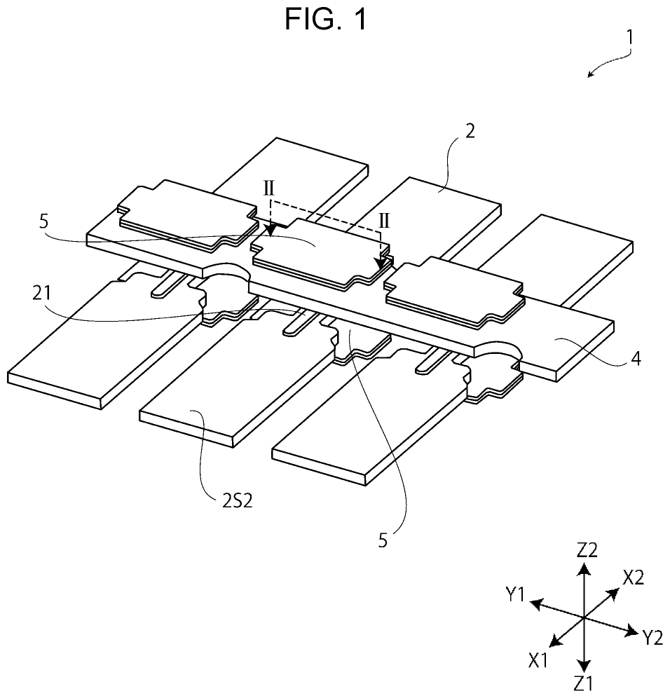

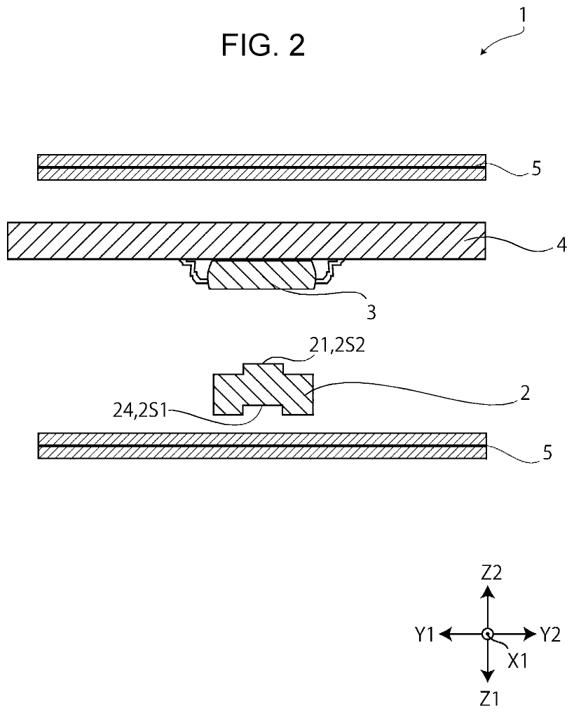

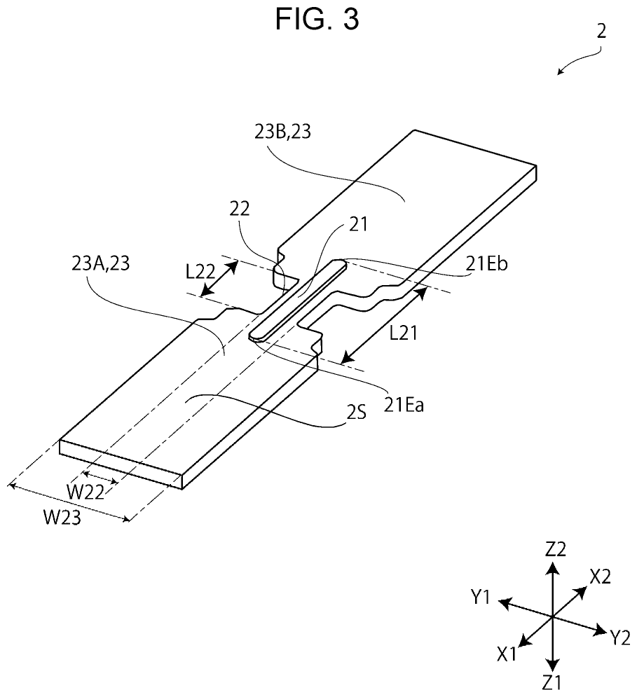

FIG. 1 is a perspective view schematically illustrating the structure of the main elements of a current sensor 1 in this embodiment. FIG. 2 is a sectional view schematically illustrating the structure of the current sensor 1 in FIG. 1 as taken along line II-II. FIG. 3 is a perspective view illustrating the structure of a bus bar 2 in the current sensor 1 illustrated in FIG. 1. In FIGS. 1 and 2, the case and the like of the current sensor 1 are omitted and only the main elements are indicated for convenience of explanation.

The current sensor 1 in this embodiment has the bus bar 2 and a magnetic sensor 3. Of the X direction, Y direction, and Z direction, which are mutually orthogonal, the bus bar 2 illustrated in FIG. 3 extends in the X direction. The bus bar 2, which is a conductor in which a current under test flows, is formed from, for example, copper, brass, aluminum, or the like in a plate shape. The normal direction of, facing the magnetic sensor 3, of the bus bar 2 is the Z direction. Although the whole of the illustrated bus bar 2 extends in the X direction (first direction), one or both of ends protruding from the case (not illustrated) of the current sensor 1 may be bent.

On the bus bar 2, a convex portion 21 is formed on a plate surface 2S2, which is on the Z2 side, along the X direction, the plate surface 2S2 being parallel to an XY plane defined by the X direction (first direction) and Y direction (second direction). Since the convex portion 21 is formed, the strength of the bus bar 2 is improved. Therefore, even when a force is applied from the outside to the bus bar 2 during, for example, assembling or a connection to a connection portion, the bus bar 2 is less likely to be deformed. Thus, since the convex portion 21 is formed to improve the strength of the bus bar 2, even when the bus bar 2 is slimmed, it is less likely to be deformed. Therefore, when the plate thickness of the bus bar 2 is reduced, the bus bar 2 can be slimed, so downsizing, profile reduction, and weight reduction are possible for the current sensor 1.

When the convex portion 21 is formed, the surface area of the bus bar 2 is enlarged, so heat generated from the bus bar 2 due to a flow of the current under test is dissipated with high efficiency. When the effect of heat dissipation from the bus bar 2 is improved, it may be possible to suppress a rise in the temperature of the bus bar 2.

The bus bar 2 may have a narrow-width portion 22 formed at a position facing the magnetic sensor 3 in the Z direction (third direction) orthogonal to the X direction and Y direction. The bus bar 2 may have wide-width portions 23A and 23B, which are continuous to the narrow-width portion 22, at both ends of the narrow-width portion 22 in the X direction. A dimension W23 of the wide-width portions 23A and 23B in the Y direction may be larger than a dimension W22 of the narrow-width portion 22 in the Y direction.

The convex portion 21 may be formed so as to be continuous from one wide-width portion 23A through the narrow-width portion 22 to the other wide-width portion 23B. That is, a length L21 of the convex portion 21 in the X direction is larger than a length L22 of the narrow-width portion 22 in the X direction. Furthermore, an end 21Ea of the convex portion 21 is positioned on the wide-width portion 23A, and an end 21Eb of the convex portion 21 is positioned on the wide-width portion 23B. Thus, due to a structure in which the convex portion 21 is formed across the whole of the narrow-width portion 22 in the X direction so as to extend to the wide-width portions 23 on both sides of the narrow-width portion 22, the strength of the narrow-width portion 22 is improved and a change in strength on the boundary between the narrow-width portion 22 and the wide-width portion 23 can be suppressed. Therefore, even when the bus bar 2 is deformed, the concentration of a force on the narrow-width portion 22 can be suppressed and the force can be dispersed to the whole of the bus bar 2, which includes the wide-width portions 23 on both sides of the narrow-width portion 22, through the convex portion 21. Thus, the bus bar 2 can be slimmed without losing its strength.

On a plate surface 2S1 of the bus bar 2 on the Z1 side, the plate surface 2S1 being opposite to the plate surface 2S2, on which the convex portion 21 is formed, on the Z2 side, a concave portion 24 is formed at the same position as the convex portion 21 when viewed along the Z direction. When the convex portion 21 is formed on the plate surface 2S2 by half punching processing so that its longitudinal direction matches the X direction, the concave portion 24 can be concurrently formed along the X direction at the same position on the plate surface 2S1 (the rear side of the convex portion 21). Therefore, it is possible to efficiently manufacture the bus bar 2 with the convex portion 21 and concave portion 24 formed at the same position when viewed along the Z direction.

In the aspect in FIG. 2, the convex portion 21 is formed on the plate surface 2S2 of the bus bar 2 and the concave portion 24 is formed in the plate surface 2S1. However, another aspect may be taken in which the convex portion 21 is formed on one of the plate surface 2S2 and plate surface 2S1 of the bus bar 2 and the other is a flat surface without the concave portion 24 being formed. Yet another aspect may be taken in which the convex portion 21 is formed on both of the plate surface 2S2 and plate surface 2S1 of the bus bar 2.

The magnetic sensor 3 is placed on a surface of a substrate 4 on the Z1 side so as to face the plate surface 2S of the bus bar 2. The magnetic sensor 3 detects an induced magnetic field, which is generated from the bus bar 2 when a current under test flows in the bus bar 2. A magnetoresistive effect element, such as a giant magnetoresistive effect element (GMR element) or a tunnel magnetoresistive effect element (TMR element), a hall element, or the like, for example, can be used as a magnetism detection element of the magnetic sensor 3. In the structure illustrated in FIGS. 1 and 2, a magnetoresistive effect element is used as an example of the magnetism detection element. When another type of magnetism detection element is used, the orientation of the detection surface and the like need to be appropriately changed during the placement of the other type of magnetism detection element.

Since the magnetic sensor 3 faces the narrow-width portion 22 of the bus bar 2, the magnetic sensor 3 measures an induced magnetic field from the narrow-width portion 22 when a current under test flows in the bus bar 2. Therefore, the shape of the narrow-width portion 22 affects the performance of the current sensor 1. Specifically, the relationship between the magnetic sensor 3 and the narrow-width portion 22 is important. If the narrow-width portion 22 is deformed, measurement precision of the current sensor 1 may be lowered because the relationship between the magnetic sensor 3 and the narrow-width portion 22 changes or the way in which an induced magnetic field is generated.

In recent years, in addition to a current sensor with an integrated bus bar, which is of a type in which the bus bar 2 is insert-molded into the case of the current sensor 1, a current sensor with a separate bus bar is proposed, which is of a type in which the bus bar 2 is attached by being inserted into an insertion hole in the case. With this type of current sensor with a separate bus bar, when the bus bar 2 is attached to the current sensor 1 or the bus bar 2 is connected to the outside, the risk is high that the narrow-width portion 22 is deformed. With the bus bar 2, the narrow-width portion 22 is relatively low in strength and is thereby likely to be deformed as described above. Thus, the narrow-width portion 22 is a region that greatly affects measurement precision of the current sensor 1. When the bus bar 2 is slimmed, therefore, the strength of the narrow-width portion 22 needs to be improved to prevent measurement precision of the current sensor 1 from being lowered due to the deformation of the narrow-width portion 22.

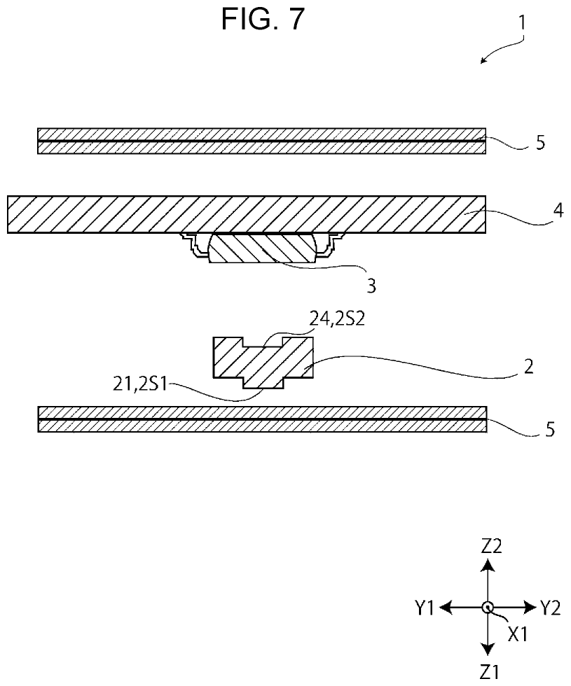

In view of this, with the current sensor 1 in this embodiment, the convex portion 21 may be formed on the narrow-width portion 22 to suppress the deformation of the narrow-width portion 22. Thus, even when the bus bar 2 is slimmed due to the improved strength of the narrow-width portion 22, it is possible to prevent measurement precision from being lowered due to the deformation of the narrow-width portion 22. Furthermore, since the concave portion 24 is formed on the surface opposite to the convex portion 21, the Y-direction component of the induced magnetic field can be increased, the induced magnetic field being generated on the side on which the concave portion 24 in the narrow-width portion 22 is present. Thus, when the magnetic sensor 3 is placed on the side facing the concave portion 24 as illustrated in FIG. 7, precision with which the current sensor 1 measures a magnetic field can be improved.

On each of the Z1 side of the bus bar 2 and the Z2 side of the substrate 4, on which the magnetic sensor 3 is mounted, metallic plate-like bodies are provided as a magnetic shield 5. The magnetic shield 5 can be formed by, for example, laminating a plurality of plate-like bodies having the same shape. Since the magnetic shields 5 can suppress magnetic noise from the outside to the magnetic sensor 3, measurement precision of the current sensor 1 is improved. Although a pair of magnetic shields 5 in a flat-plate shape are illustrated in FIG. 1, only one magnetic shield 5 may be provided. The magnetic shield 5 may be U-shaped when viewed along the X direction.

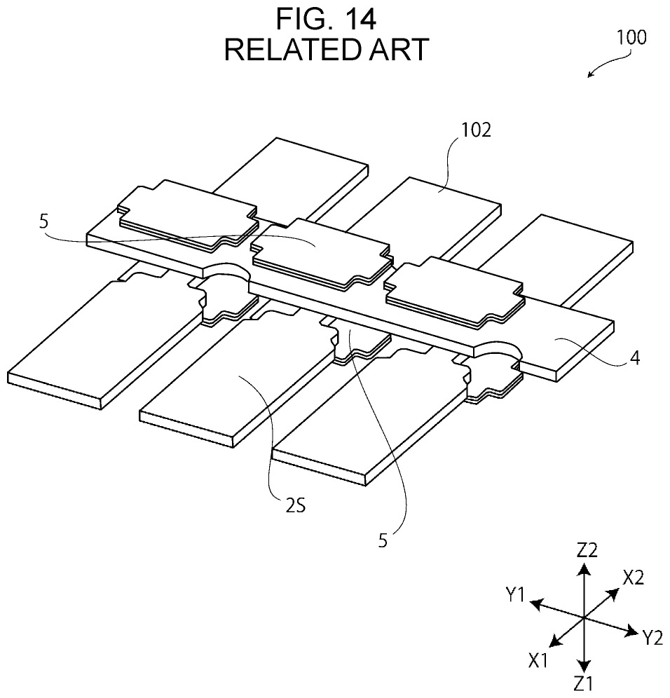

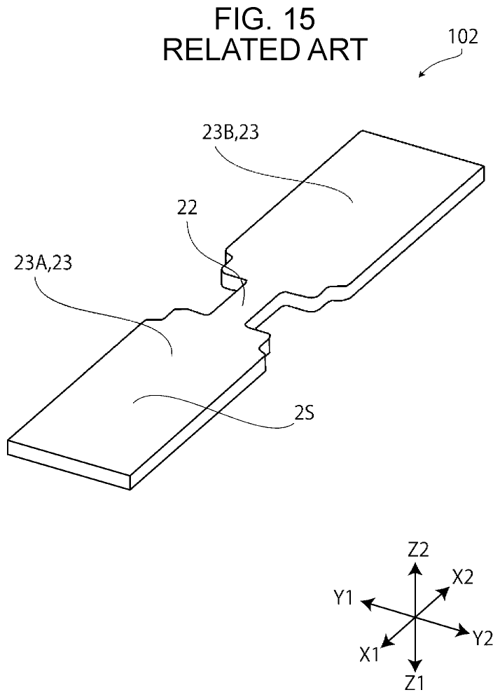

FIG. 14 is a perspective view schematically illustrating the structure of the main elements of a current sensor 100 in related art. FIG. 15 is a perspective view illustrating the structure of a bus bar 102 in the current sensor 100 in FIG. 14.

As illustrated in these drawings, the bus bar 102 included in the current sensor 100 in related art differs from the bus bar 2 included in the current sensor 1 in that the convex portion 21 is not formed on the narrow-width portion 22. That is, a structure has been used in which the plate surfaces on the both sides of the narrow-width portion 22 are formed as flat surfaces.

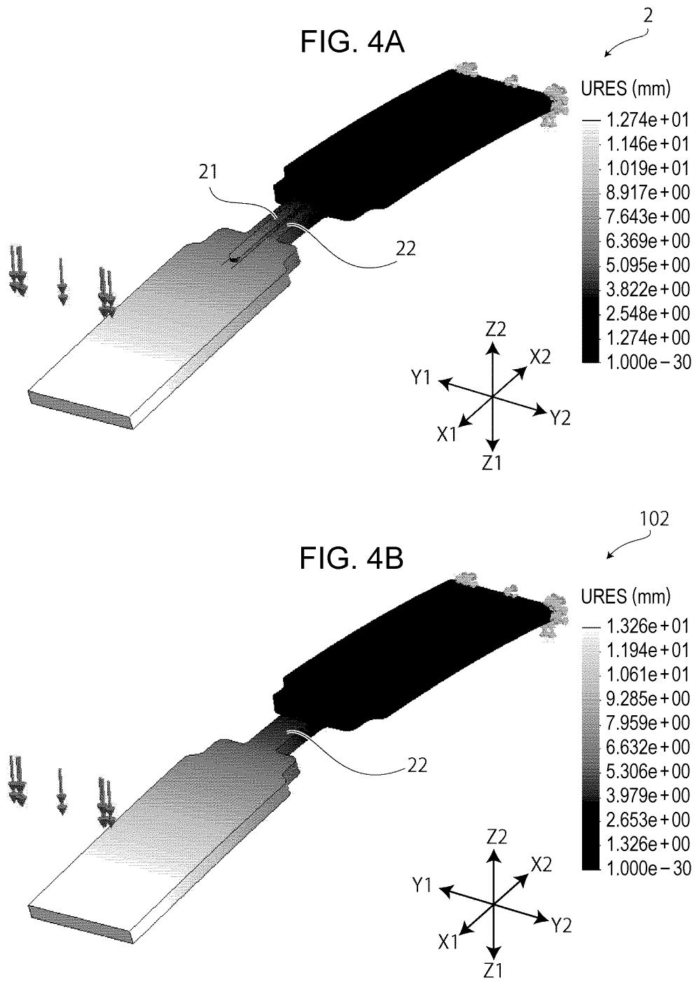

FIG. 4A is a perspective view illustrating simulation results for deviation caused when a force is applied in the Z1 direction, in a state in which an end on the X2 side of the bus bar 2 in FIG. 3 is fixed, to an end on the X1 side. FIG. 4B is a perspective view illustrating simulation results for deviation when the simulation was performed for the bus bar 102 in FIG. 15 under the same conditions as for the bus bar 2 in FIG. 3.

In the simulation results illustrated in FIGS. 4A and 4B, a difference in deviation at each region is not indicated as a difference in the shading of color. This is because the shading of color in the simulation results does not represent the magnitude of the amount of deviation at each region, but represents the ratio of the amount of deviation at each region to the maximum amount of deviation in the bus bar 2 or bus bar 102. That is, in comparison between the simulation results illustrated in FIGS. 4A and 4B, these simulation results do not mean that the amounts of deviation at regions indicated by the same shading are the same.

In each simulation result, the amount of deviation at each region is indicated as a numeric value assigned to the scale on the right side. At the end on the X1 side, for example, the numeric value indicating the amount of deviation is 1.274e+01 (mm) in FIG. 4A and is 1.326e+01 (mm) in FIG. 4B. This shows that there is a difference in the amount of deviation. As for approximate values evaluated in consideration of the numeric values indicated on the scales, the amount of deviation of the narrow-width portion 22 illustrated in FIG. 4A, which has the convex portion 21, was 2.548 to 5.095 and the amount of deviation of the narrow-width portion 22 in FIG. 4B, which lacks the convex portion 21, was 2.653 to 6.632. It is found from these results that when the convex portion 21 is formed on the narrow-width portion 22, the amount of deviation in the narrow-width portion 22 is suppressed.

### Variation

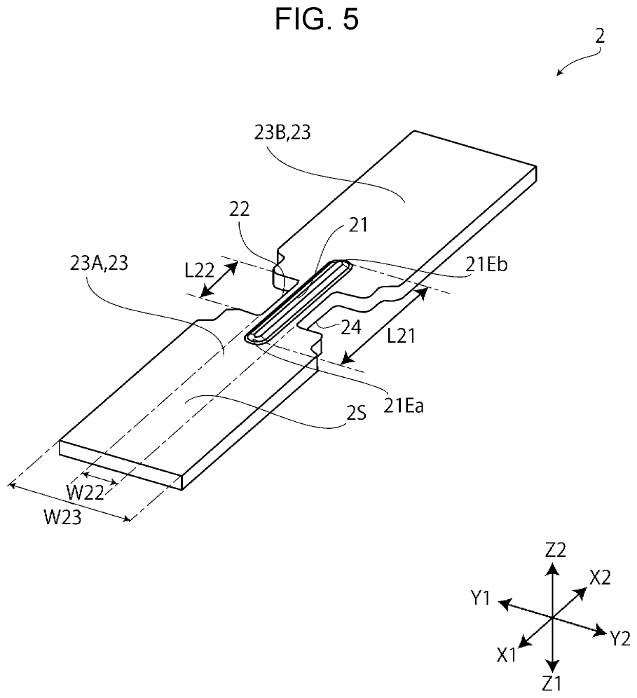

FIG. 5 is a perspective view illustrating the structure of a variation of the bus bar 2 in the current sensor 1 in FIG. 1. The bus bar 2 illustrated in the drawing is similar to the bus bar 2 illustrated in FIGS. 3 and 4A in terms of the structure such as for dimensions. In contrast to the bus bar 2 illustrated in FIGS. 3 and 4A, which is formed by, for example, half punching processing, the convex portion 21 and concave portion 24 of the bus bar 2 illustrated in FIG. 5 can be formed by, for example, bead processing. In bead processing, the convex portion 21 and concave portion 24 can be concurrently machined as in half punching processing.

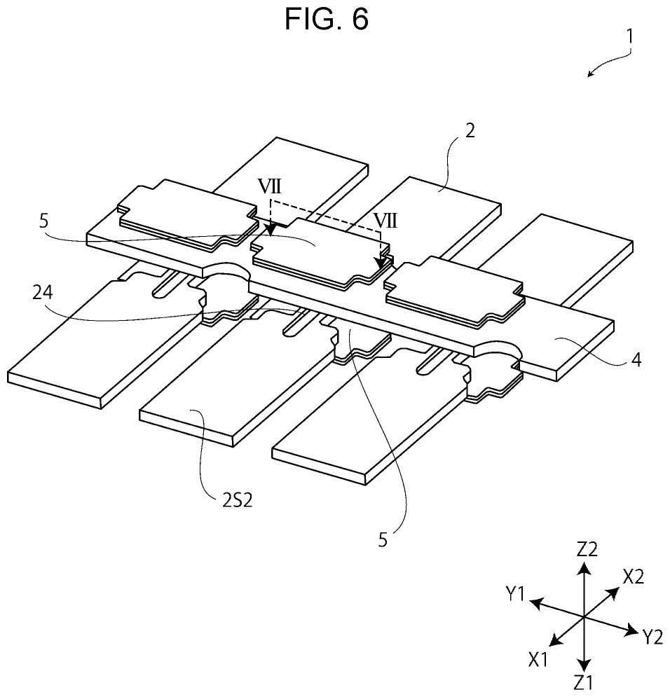

FIG. 6 is a perspective view schematically illustrating the structure of the main elements in the variation of the current sensor 1 in FIG. 1. FIG. 7 is a sectional view schematically illustrating the structure of the current sensor 1 in FIG. 6 as taken along line VII-VII.

As illustrated in these drawings, the above variation has a structure in which the bus bar 2 in the current sensor 1 in FIG. 1 is reversed in the Z direction. Specifically, with the bus bar 2 included in the current sensor 1 in the variation, the convex portion 21 may be formed on the plate surface (first plate surface) 2S1 on the Z1 side opposite to the magnetic sensor 3, and the concave portion 24 may be formed along the X direction on the plate surface (second plate surface) 2S2 on the Z2 side opposite to the plate surface 2S1. Then, the magnetic sensor 3 may be placed so as to face the concave portion 24 in the bus bar 2, as illustrated in FIGS. 6 and 7.

When the concave portion 24 is formed on the rear side of the convex portion 21 in this way, the magnetic field component of the induced magnetic field, eligible for detection by the magnetic sensor 3, from the bus bar 2 is increased around the periphery of the concave portion 24, the magnetic field component being parallel to the plate surface 2S2 and being oriented in the Y direction orthogonal to the X direction. Therefore, when the concave portion 24 is provided in the plate surface 2S2 on the side, of the bus bar 2, facing the magnetic sensor 3, measurement precision of the magnetic sensor 3 is improved and the current sensor 1 has superior measurement precision.

With the bus bar 2, the convex portion 21 and concave portion 24 may be formed at the same position when viewed along the Z direction, as illustrated in FIGS. 6 and 7. Since the bus bar 2 with the convex portion 21 and concave portion 24 formed at the same position when viewed along the Z direction can be easily formed by half punching processing or the like, the bus bar 2 is advantageous from the viewpoint of the manufacturing efficiency of the bus bar 2. When the strength of the bus bar 2 is enhanced by the convex portion 21 and the magnetic sensor 3 is placed so as to face the concave portion 24, measurement precision of the current sensor 1 is improved.

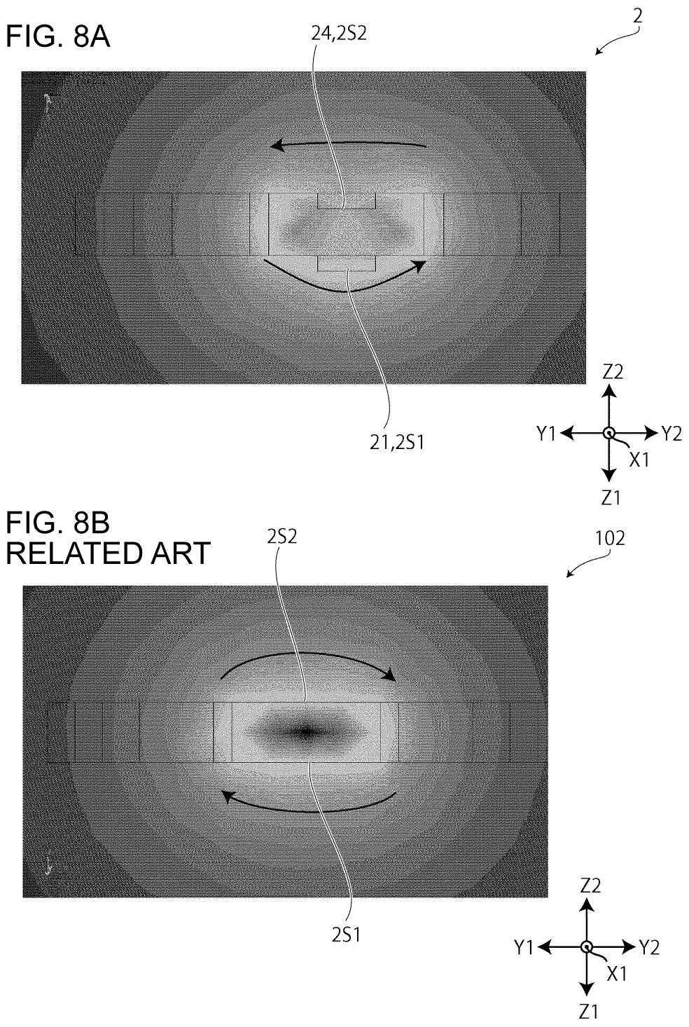

FIG. 8A illustrates simulation results indicating the strength of an induced magnetic field around the periphery of the bus bar 2 in the current sensor 1 in FIGS. 6 and 7. FIG. 8B illustrates simulation results indicating the strength of an induced magnetic field around the periphery of the bus bar 102 in the current sensor 100 in related art in FIG. 14.

Each solid-black arrow in FIG. 8A schematically indicates part of an induced magnetic field generated around the bus bar 2. Similarly, each solid-black arrow in FIG. 8B schematically indicates part of an induced magnetic field generated around the bus bar 102.

The induced magnetic field generated in the vicinity of the plate surface 2S (see FIG. 15) on the Z2 side of the bus bar 102, in which the concave portion 24 is not formed, is formed in an arc shape in which the arch line is more distant from the plate surface 2S in the vicinity of the center of the bus bar 102 than in the vicinity of its both ends in the Y direction, as illustrated in FIG. 8B.

In contrast to this, as for the bus bar 2, in which the concave portion 24 is formed in the rear side of the convex portion 21, an induced magnetic field substantially parallel to the Y direction was formed in the vicinity of the plate surface 2S2 (see FIG. 7) on the Z2 side, on which the concave portion 24 is formed, as illustrated in FIG. 8A. That is, it can be said that the induced magnetic field generated in the vicinity of the concave portion 24 included more components, detectable by the magnetic sensor 3, parallel to the Y direction in the induced magnetic field than the induced magnetic field generated when the concave portion 24 is not formed. Thus, when the magnetic sensor 3 is placed so as to face the concave portion 24, the induced magnetic field from the bus bar 2 can be precisely measured with the magnetic sensor 3, the induced magnetic field being generated when a current under test flows.

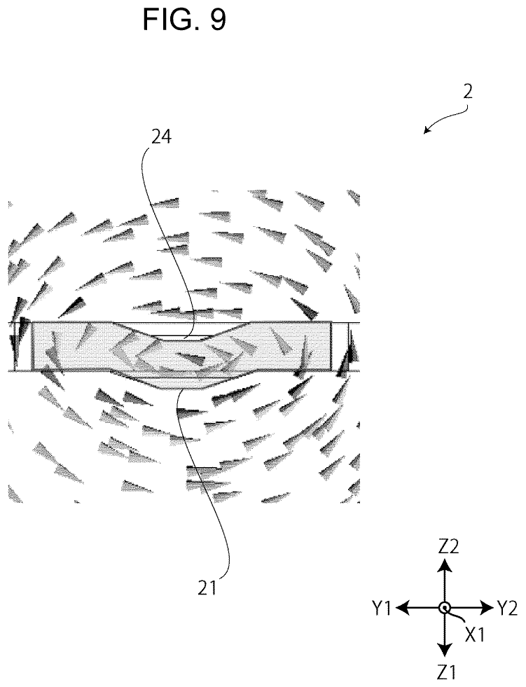

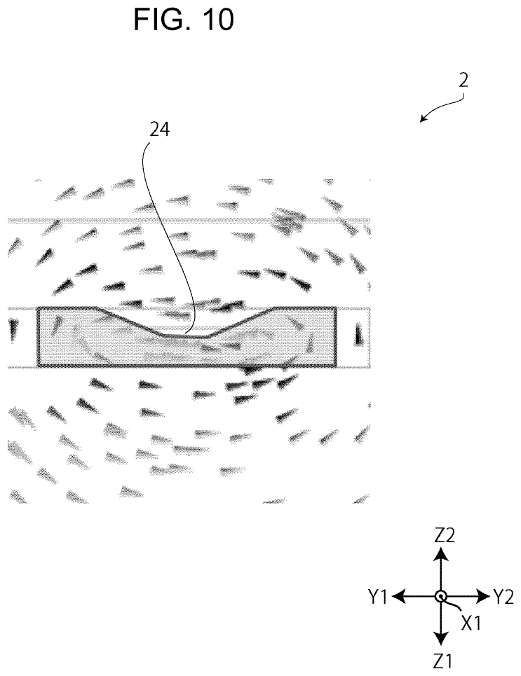

Next, the bus bar 2 in which only the concave portion 24 is formed without the convex portion 21 being formed will be compared as a reference example. FIG. 9 illustrates simulation results indicating the directions and strength of an induced magnetic field around the periphery for the variation of the bus bar 2 in the current sensor 1 in FIG. 6. FIG. 10 illustrates simulation results indicating the directions and strength of an induced magnetic field around the periphery of the bus bar 2 in the reference example.

From the simulation results illustrated in these drawings as well, it is indicated that when the concave portion 24 is formed in the plate surface 2S2 of the bus bar 2, an induced magnetic field including more Y-direction components is formed in the vicinity of the concave portion 24.

In comparison with the structure in related art illustrated in FIG. 8B, it appears that the induced magnetic field formed around the periphery of the concave portion 24 similarly includes more Y-direction components in the structure in the reference example as well. However, another induced magnetic field is also formed so as to follow the inner surface shape of the concave portion 24. When compared with the structure in this embodiment illustrated in FIG. 9, therefore, an induced magnetic field including more Y-direction components is not formed in the vicinity of the concave portion 24.

When only the concave portion 24 is formed in the bus bar 2 without the convex portion 21 being formed, if the bus bar 2 is slimmed as a means for downsizing and/or profile reduction of the current sensor 1, the strength becomes lower than when slimming is performed with the structure in related art (in which the concave portion 24 is not formed) remaining unchanged.

When the concave portion 24 is formed by pressing processing, there is no space into which the metal that has been present in the recessed portion is escaped, the base material around the periphery of the concave portion 24 is compressed and the hardness of the bus bar 2 is thereby increased. However, elasticity is lowered. Therefore, if some kind of bending stress is applied to the vicinity of the concave portion 24, the bus bar 2 is likely to be broken. To prevent this, it is preferable to perform half punching processing to form the convex portion 21 and concave portion 24 in the same place on the plate surface 2S2 and on the plate surface 2S1.

From the above, when the convex portion 21 is formed on the bus bar 2 and the concave portion 24 is also formed on the rear side of the convex portion 21, it becomes possible for the bus bar 2 to enable the magnetic sensor 3 to easily measure the induced magnetic field from the bus bar 2 with high precision, and even when the bus bar 2 is slimmed, to suppress a drop in strength. The method of forming the convex portion 21 and concave portion 24 is not limited to half punching processing. A method other than half punching processing may be used.

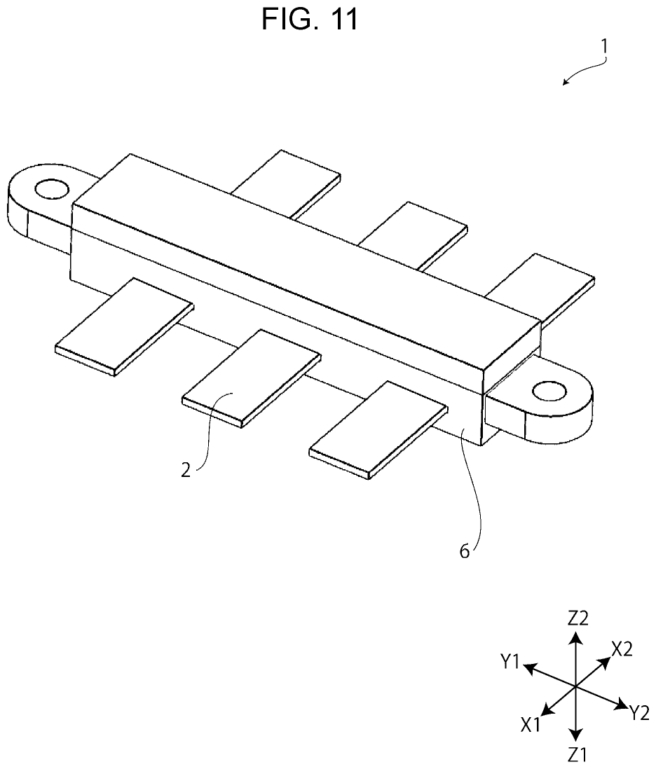

FIG. 11 is a perspective view schematically illustrating a structure in another variation of the current sensor 1 in FIG. 1. The current sensor 1 illustrated in the drawing may have a case 6, formed from a resin material or the like, in which the magnetic sensor 3 (see FIG. 2) is stored. The bus bar 2 may be insert-molded into the case 6.

In a structure in which the bus bar 2 is insert-molded into the case 6, the bus bar 2 and magnetic sensor 3 can have a predetermined positional relationship that can be reliably maintained. Therefore, the current sensor 1 has superior measurement precision.

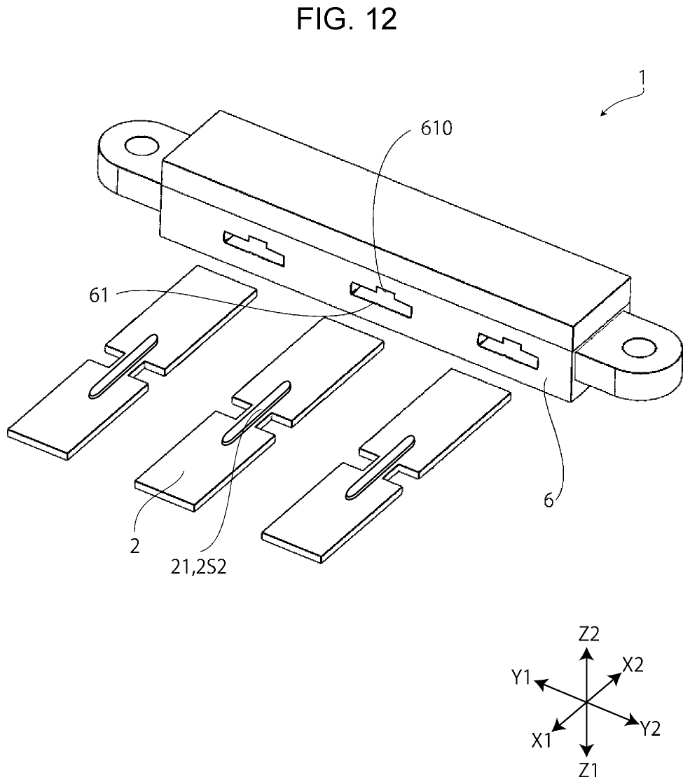

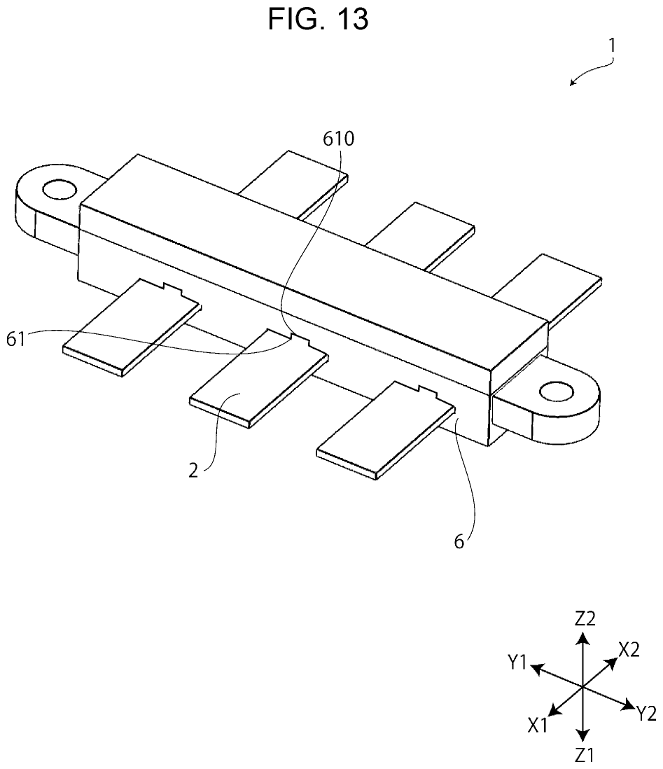

FIG. 12 is an exploded perspective view schematically illustrating the structure in the other variation of the current sensor 1 in FIG. 1. FIG. 13 is a perspective view illustrating a state in which the current sensor 1 in FIG. 12 has been assembled.

As illustrated in these drawings, the present invention can be practiced as the current sensor 1 having the magnetic sensor 3 (see FIG. 2) and case 6. In a structure in which the bus bar 2 is attachable to the case 6, rather than a structure in which the bus bar 2 is formed integrally with the case 6, the degree of freedom of the shape of the bus bar 2 is increased, so the current sensor 1 becomes highly versatile.

The case 6 may have an insertion hole 61, into which the bus bar 2, on the plate surface 2S2 of which the convex portion 21 is formed along the extending direction of the bus bar 2, can be inserted. The insertion hole 61 may have a guide 610 through which the convex portion 21 on the bus bar 2 is passed. Since the guide 610 is formed in the insertion hole 61 in the case 6, it is possible to easily insert the bus bar 2 into the insertion hole 61.

The embodiment disclosed in this description is exemplary in all points. The present invention is not restricted to this embodiment. The scope of the present invention is not indicated by the description of only the embodiment described above but is indicated by the scope of the claims. It is intended that meanings equivalent to the scope of the claims and all modifications in the scope are included.

The present invention is useful, for example, as a current sensor that measures a current under test that flows in a device to control a power supply system in a vehicle or the like that has various devices and as a bus bar used in the current sensor.

1. A current sensor comprising:
a bus bar having a plate surface extending in a first direction and having a width in a second direction orthogonal to the first direction; and
a magnetic sensor,
wherein the bus bar includes:
a convex portion formed on the plate surface thereof and extending along the first direction.

2. The current sensor according to claim 1,
wherein the bus bar further includes:
a narrow-width portion provided at a position along the first direction at which the bus bar faces the magnetic sensor in a third direction orthogonal to the first direction and to the second direction; and
wide-width portions provided on both sides of the narrow-width portion in the first direction, the wide-width portions being continuously formed with the narrow-width portion and having a width greater than that of the narrow-width portion,
and wherein the convex portion is formed on the narrow-width portion.

3. The current sensor according to claim 2, wherein the convex portion is formed continuously from one of the wide-width portions through the narrow-width portion to another of the wide-width portions.

4. The current sensor according to claim 2,
wherein the bus bar further includes:
a concave portion formed on another plate surface opposite to the plate surface on which the convex portion is formed, the concave portion extending along the first direction,
and wherein the magnetic sensor is placed so as to face the concave portion.

5. The current sensor according to claim 4, wherein the convex portion and the concave portion are formed at a same position viewed from the third direction.

6. The current sensor according to claim 1, further comprising:
a case in which the magnetic sensor is housed,
wherein the bus bar is formed by insert-molding with the case.

7. A current sensor comprising:
a bus bar extending in a first direction;
a magnetic sensor; and
a case,
wherein the bus bar has a plate surface on which a convex portion is formed along the first direction, and the case has an insertion hole through which the bus bar is inserted.

8. The current sensor according to claim 7, wherein the insertion hole has a guide through which the convex portion is passed.

9. A bus bar comprising:
a plate surface extending in a first direction and having a width in a second direction orthogonal to the first direction,
wherein the bus bar includes:
a narrow-width portion formed at a position to face a magnetic sensor in a third direction orthogonal to the first direction and to the second direction;
wide-width portions provided on both sides of the narrow-width portion in the first direction, the wide-width portions being continuously formed with the narrow-width portion and having a width greater than that of the narrow-width portion; and
a convex portion formed on the plate surface in the narrow-width portion, the convex portion extending along the first direction.
